(19) United States
(12) Patent Application Publication
(10) Pub. No.: US 2017/0200750 A1
(43) Pub. Date: Jul. 13, 2017

(54) METHOD FOR MANUFACTURING ARRAY SUBSTRATE

(71) Applicant: Wuhan China Star Optoelectronics Technology Co., Ltd., Wuhan City (CN)

(72) Inventors: Yuanfu Liu, Wuhan City (CN); Fuhsiung Tang, Wuhan City (CN)

(21) Appl. No.: 15/137,001

(22) Filed: Apr. 25, 2016

(30) Foreign Application Priority Data
Jan. 12, 2016 (CN) 201610020299.6

(51) Int. Cl. H01L 27/12; G02F 1/1339; G02F 1/1333; G02F 1/1368; H01L 21/311; G06F 3/041

(52) U.S. Cl. CPC H01L 27/1288; H01L 21/31144; G06F 3/0412; G02F 1/13338; G02F 1/1368; G02F 1/1339; G06F 2203/04103

(57) ABSTRACT

Provided is a method for manufacturing an array substrate, in which a planarization layer mask includes a strip pattern that is provided for forming a groove and has two opposite sides along which taper modification patterns are provided so as to reduce taper of a groove formed in a planarization layer, making a slope thereof less steep, thereby preventing shorting of signal lines caused by residues of metal or ITO in a subsequent operation and thus increasing product yield. For the groove associated portion of an array substrate involving an in-cell touch structure, there is no need to change line for the touch sensing lines so as to lower down the difficulty of the operation and increase product yield.

### BACKGROUND OF THE INVENTION

1. Field of the Invention

The present invention relates to the field of display technology, and in particular to a method for manufacturing an array substrate.

2. The Related Arts

With the progress of the display technology, flat panel display devices, such as liquid crystal displays (LCDs), due to various advantages, such as high image quality, low power consumption, thin device body, and wide range of applications, have been widely used in all sorts of consumer electronic products, including mobile phones, televisions, personal digital assistants (PDAs), digital cameras, notebook computers, and desktop computers, making them the main stream of display devices.

Most of the liquid crystal display devices that are currently available in the market are backlighting LCDs, which comprise a liquid crystal display panel and a backlight module. The working principle of the liquid crystal display panel is that liquid crystal molecules are disposed between two parallel glass substrates and multiple vertical and horizontal tiny conductive wires are arranged between the two glass substrates, wherein the liquid crystal molecules are controlled to change directions through application of electricity thereto in order to refract out light emitting from the backlight module to generate an image.

The liquid crystal display panel is generally made up of a color filter (CF) substrate, a thin-film transistor (TFT) substrate, liquid crystal (LC) interposed between the CF substrate and the TFT substrate, and sealant and is generally manufactured with a process involving an anterior stage of array related operations (for thin film, lithography, etching, and film peeling), an intermediate-stage of cell related operations (for lamination of the TFT substrate and the CF substrate), and a posterior-stage of module assembly related operation (for combining a drive integrated circuit (IC) and a printed circuit board). Among these stages, the anterior-stage of array related operations generally involve the formation the TFT substrate for controlling the movement of liquid crystal molecules; the intermediate-stage of cell related operations generally involve filling liquid crystal between the TFT substrate and the CF substrate; and the posterior-stage of module assembly related operations generally involve the combination of the drive IC and the printed circuit board for driving the liquid crystal molecules to rotate for displaying of images.

To overcome the actual problems of maintaining the brightness of a screen invariable without raising power consumption of the backlighting illumination, technical persons have figured out various solutions to increase transmission rate. A common way that is adopted currently involves the inclusion of a planarization layer to reduce the capacitance between the pixel electrode and the common electrode and the signal lines or scan lines. Generally, the planarization layer has a thickness of at least 1.5 μm and this would make the aperture ratio increased. On the other hand, to suit the need for narrowed bezels for devices, a common solution is to shrink the width of the sealant and bezel of the liquid crystal display panel. For not deteriorating the adhesion of the sealant to the TFT substrate and the CF substrate, it is common to form a groove in the planarization layer (PLN) along a circumference of the TFT substrate in order to maintain the contact area between the sealant and the TFT substrate. However, this causes a technical problem. The groove of the PLN is generally a relatively deep groove having a depth of at least 1.5 μm and the sides of the groove have significant taper, which generally exceeds 50 degrees. This leads to a great amount of indium tin oxide (ITO) left in the groove in a subsequent operation related to an ITO pixel electrode and such ITO would cause undesired shorting of the signal lines, resulting in poor displaying. Shorting of the signal lines caused by ITO is an issue that small- and medium-sized panels face.

As shown in FIGS. 1 and 2, a conventional process for manufacturing an array substrate comprises the following steps: forming a TFT layer 200 on a substrate 100, forming a planarization layer 300 by coating an organic material on the TFT layer 200, and applying a photolithographic process to form a groove 320 in a circumferential area of the planarization layer 300; depositing an ITO film 400 on the planarization layer 300 after the formation of the planarization layer 300, and then applying a photolithographic process to pattern the ITO film 400, wherein, firstly, photoresist is coated on the ITO film 400 to form a photoresist layer 500 and then, the photoresist layer 500 is subjected to exposure and development. Since the taper of the groove 320 is relatively large, photoresist residue 530 may be left in the groove 320 (see FIG. 1) after the operations of exposure and development. Due to being shielded by the photoresist residue, the ITO film 430, after being etched away, would leave ITO residue 430 in the groove 320 (see FIG. 2). Similarly, for an array substrate involving an in-cell touch structure, metal residue of M3 (the metal layer where a touch sensing line Rx is located) would occur, leading to incorrect touch signal and thus affecting product quality.

### SUMMARY OF THE INVENTION

An object of the present invention is to provide a method for manufacturing an array substrate, which reduces side taper of a groove formed in a circumferential area of a planarization layer, making the slope thereof less steep and lowered, in order to prevent shorting of signal lines caused by residues of metal or ITO in a subsequent operation and thereby increasing product yield.

To achieve the above objects, the present invention provides a method for manufacturing an array substrate, which comprises the following steps:

(1) providing a base plate, forming a thin-film transistor (TFT) layer on the base plate, and then coating an organic photoresist material on the TFT layer to form a planarization layer;

(2) providing a planarization layer mask, wherein the planarization layer mask comprises a plurality of groove patterns corresponding to a circumferential area of the planarization layer and the groove patterns each comprise a strip pattern for forming a groove in the planarization layer and taper modification patterns arranged on two opposite sides of the strip pattern, wherein the taper modification patterns each comprise a plurality of miniature patterns densely and closely distributed along a side border of the strip pattern and the miniature patterns have a width that is reduced from the side border of the strip patterns in an outward direction; and

(3) using the planarization layer mask to subject the planarization layer to exposure and development so as to form a plurality of grooves in the circumferential area of the planarization layer, wherein since the planarization layer mask comprises the taper modification patterns that are provided on the two sides of each of the strip patterns for forming the grooves, the angle of side taper of the grooves is reduced to make a slope less steep.

The base plate comprises a transparent plate; and the TFT layer comprises a buffer layer, a gate insulation layer, an interlayer dielectric layer, and an active layer, a gate electrode, and source/drain electrodes arranged among the buffer layer, the gate insulation layer, the interlayer dielectric layer, and the planarization layer.

The miniature patterns each comprise a plurality of circular patterns that is sequentially lined up in the outward direction and has diameters that are gradually reduced.

The diameters of the circular patterns are in the range of 1-3 μm.

The miniature patterns each comprise a triangular pattern.

The triangular patterns has a width that is in the range of 1-3 μm.

When the planarization layer is formed of a positive organic photoresist material, the groove patterns of the planarization layer mask are transparent, while the remaining portion is non-transparent; and alternatively, when the planarization layer is formed of a negative organic photoresist material, the groove patterns of the planarization layer mask are non-transparent, while a remaining portion is transparent.

The taper of the grooves formed in step (3) has an angle between 20 degrees and 50 degrees.

The method further comprises step (4): depositing an oxide conductive layer on the planarization layer and applying a photolithographic process to pattern the oxide conductive layer so as to form a pixel electrode, wherein since the taper of the grooves formed in step (3) is less steep, residues of the oxide conductive layer in the grooves is avoided.

The method further comprises step (4′): depositing a metal layer on the planarization layer and applying a photolithographic process to pattern the metal layer so as to form a touch sensing line, wherein since the taper of the grooves formed in step (3) is less steep, residues of the metal layer in the grooves is avoided.

The efficacy of the present invention is that the present invention provides a method for manufacturing an array substrate, in which a planarization layer mask comprises a strip pattern that is provided for forming a groove and has two opposite sides along which taper modification patterns are provided so as to reduce or lower taper of a groove formed in a planarization layer, making a slope thereof less steep, thereby preventing shorting of signal lines caused by residues of metal or ITO in a subsequent operation and thus increasing product yield. For the groove associated portion of an array substrate involving an in-cell touch structure, there is no need to change line for the touch sensing lines so as to lower down the difficulty of the operation and increase product yield.

For better understanding of the features and technical contents of the present invention, reference will be made to the following detailed description of the present invention and the attached drawings. However, the drawings are provided for the purposes of reference and illustration and are not intended to impose limitations to the present invention.

### BRIEF DESCRIPTION OF THE DRAWINGS

The technical solution, as well as other beneficial advantages, of the present invention will be apparent from the following detailed description of embodiments of the present invention, with reference to the attached drawing. In the drawing:

FIGS. 1 and 2 are schematic view illustrating a conventional process for manufacturing an array substrate;

FIG. 3 is a schematic view illustrating step 1 of a method for manufacturing an array substrate according to the present invention;

FIG. 4 is a schematic view illustrating a first example of an planarization layer mask provided in step 2 of the method for manufacturing an array substrate according to the present invention;

FIG. 5 is an enlarged view of a marked area A of FIG. 4;

FIG. 6 is a schematic view illustrating a second example of the planarization layer mask provided in step 2 of the method for manufacturing an array substrate according to the present invention;

FIG. 7 is an enlarged view of a marked area B of FIG. 6;

FIG. 8 is a schematic view illustrating step 3 of the method for manufacturing an array substrate according to the present invention;

FIGS. 9-10 are schematic views illustrating step 4 of a method for manufacturing an array substrate according to the present invention;

FIGS. 11-12 are schematic views illustrating step 4′ of a method for manufacturing an array substrate according to the present invention.

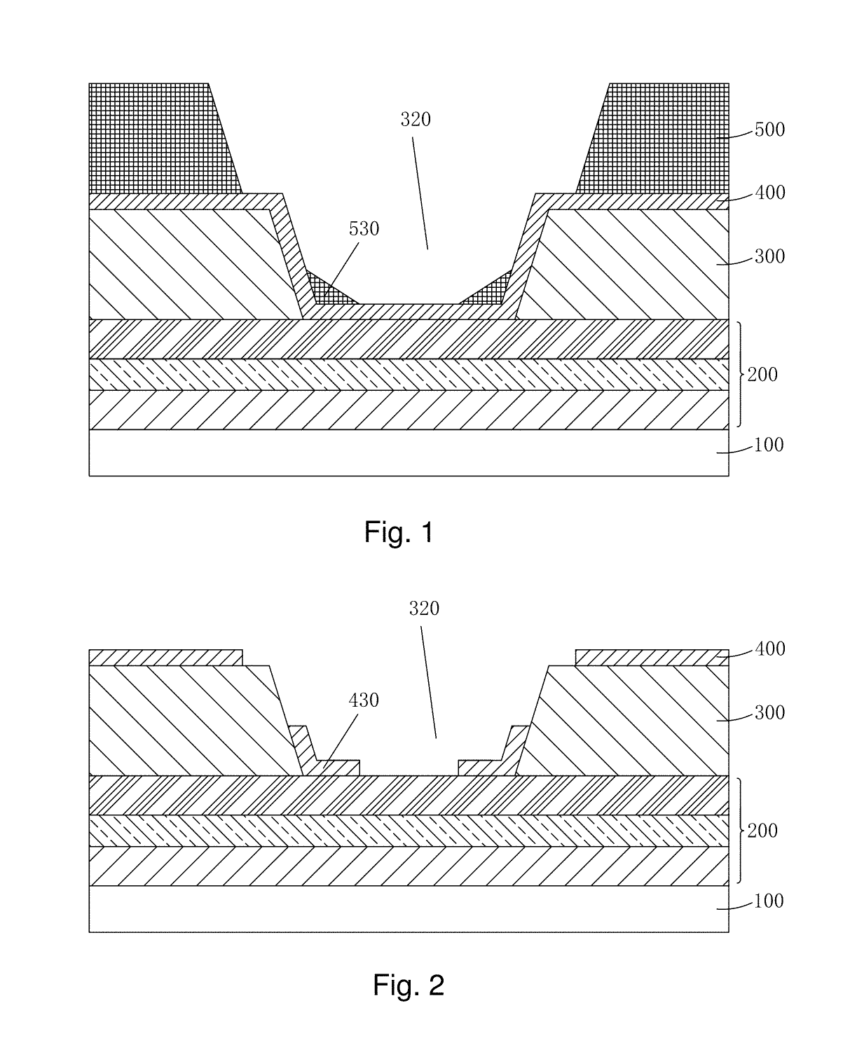

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

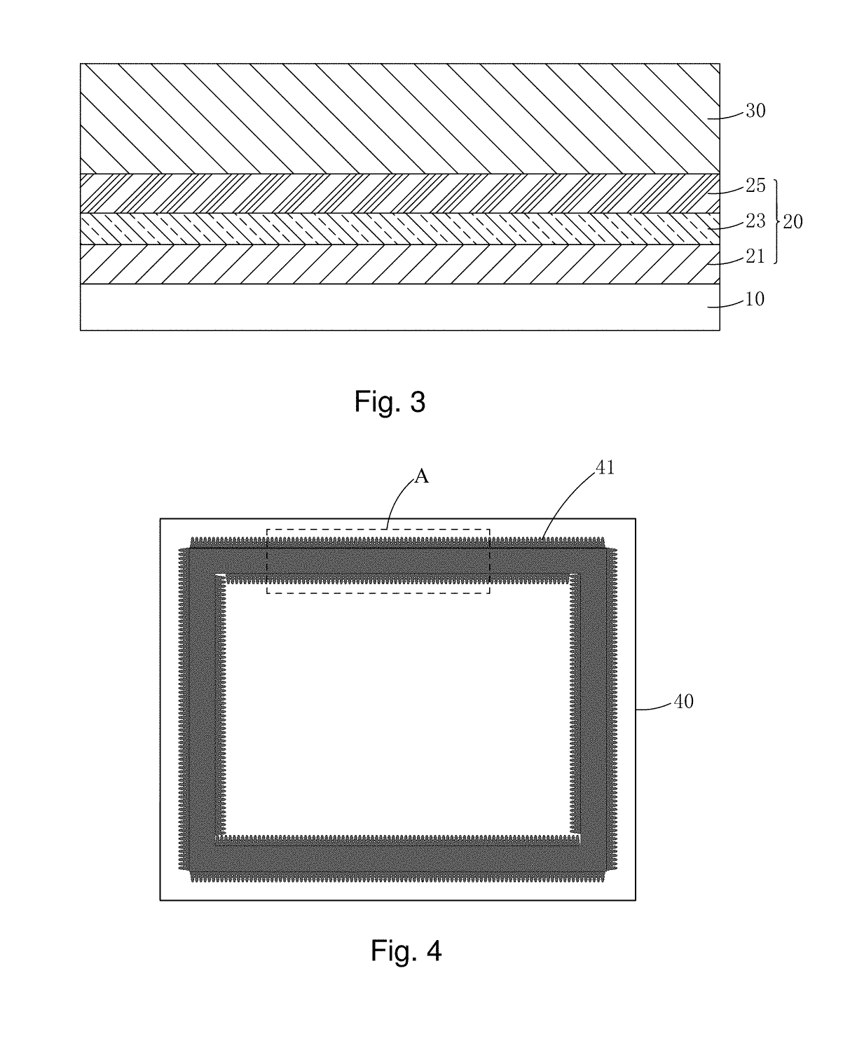

Referring to FIGS. 3-12, the present invention provides a method for manufacturing an array substrate, which comprises the following steps:

Step 1: as shown in FIG. 3, providing a base plate 10, forming a thin-film transistor (TFT) layer 20 on the base plate 10, and then coating an organic photoresist material on the TFT layer 20 to form a planarization layer 30.

Specifically, the base plate 10 is a transparent plate, and is preferably a glass plate.

Specifically, as shown in FIG. 3, the TFT layer 20 comprises a buffer layer 21, a gate insulation layer 23, and an interlayer dielectric layer 25. Further, the TFT layer 20 also comprises an active layer, a gate electrode, and source/drain electrodes arranged among the buffer layer 21, the gate insulation layer 23, the interlayer dielectric layer 25, and the planarization layer 30.

Specifically, the buffer layer 21, the gate insulation layer 23, and the interlayer dielectric layer 25 are each a silicon oxide (SiOₓ), a silicon nitride (SiNₓ), or a combined layer comprising a silicon oxide layer and a silicon nitride layer stacked on each other.

Step 2: as shown in FIGS. 4-7, providing a planarization layer mask 40, wherein the planarization layer mask 40 comprises a plurality of groove patterns 41 corresponding to a circumferential area of the planarization layer 30 and the groove patterns 41 each comprise a strip pattern 401 for forming a groove in the planarization layer and taper modification patterns 402 arranged on two opposite sides of the strip pattern 401, wherein the taper modification patterns 402 each comprise a plurality of miniature patterns 421 densely and closely distributed along a side border of the strip pattern 401 and the miniature patterns 421 have a width that is reduced from the side border of the strip patterns 401 in an outward direction.

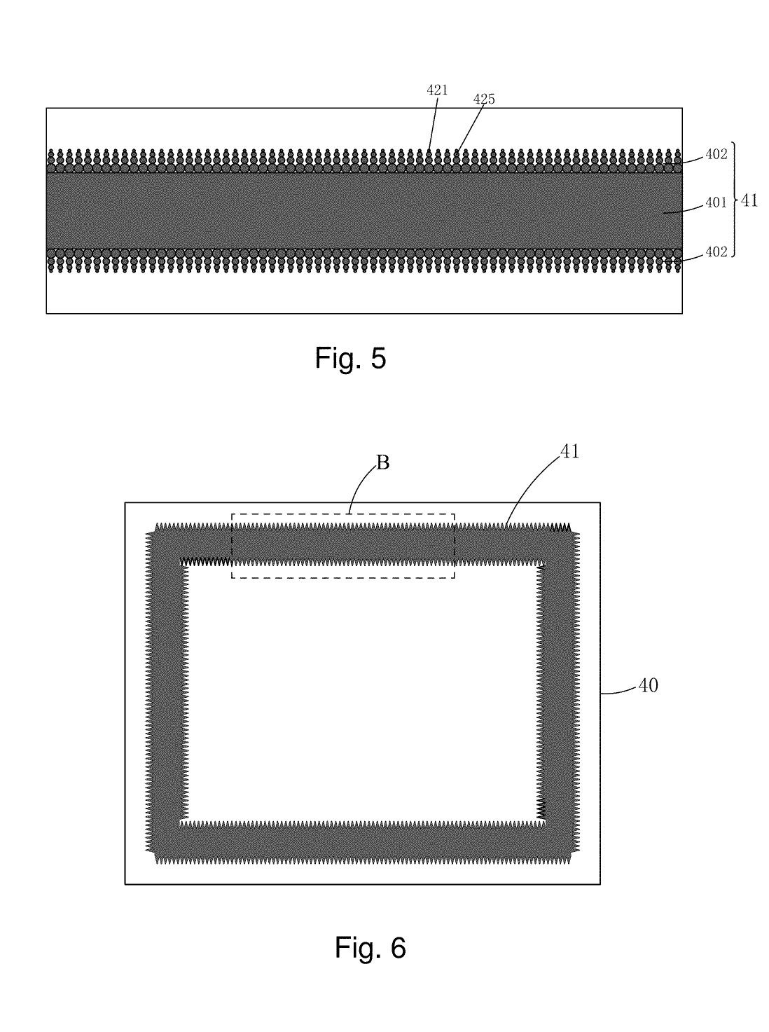

Specifically, as shown in FIGS. 4-5, the miniature patterns 421 each comprise a plurality of circular patterns 425 that is sequentially lined up in the outward direction and has diameters that are gradually reduced. Specifically, the diameters of the circular patterns 425 are in the range of 1-3 μm.

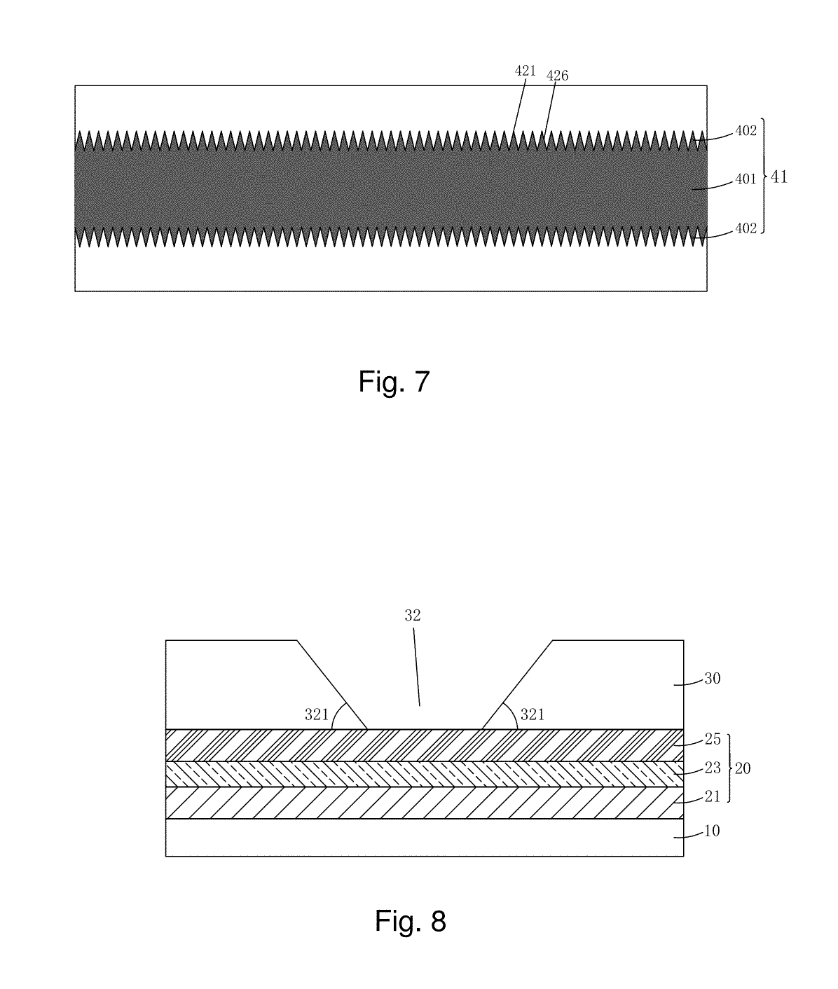

Alternatively, as shown in FIGS. 6-7, the miniature patterns 421 each comprise a triangular pattern 426. Specifically, the triangular pattern 426 has a width that is in the range of 1-3 μm.

Specifically, when the planarization layer 30 is formed of a positive organic photoresist material, the groove patterns 41 of the planarization layer mask 40 are transparent, while the remaining portion is non-transparent.

Alternatively, when the planarization layer 30 is formed of a negative organic photoresist material, the groove patterns 41 of the planarization layer mask 40 are non-transparent, while a remaining portion is transparent.

Step 3: as shown in FIG. 8, using the planarization layer mask 40 to subject the planarization layer 30 to exposure and development so as to form a plurality of grooves 32 in the circumferential area of the planarization layer 30, wherein since the planarization layer mask 40 comprises the taper modification patterns 402 that are provided on the two sides of each of the strip patterns 401 for forming the grooves, the angle of side taper 321 of the grooves 32 is reduced to make a slope less steep.

Specifically, the grooves 32 are provided to correspond to frame sealant of a liquid crystal display panel in order to increase a contact area between the frame sealant and the array substrate.

Specifically, during exposure, the taper modification patterns 402 provides an effect similar to half-toning so as to reduce or lowered the taper 321 of the grooves 32 in the circumferential area of the planarization layer 30, thereby preventing shorting of signal lines resulting from residues of metal or ITO in a subsequent operation and thus increasing product yield.

Specifically, the angle of the taper 321 of the grooves 32 formed in Step 3 is between 20 degrees and 50 degrees.

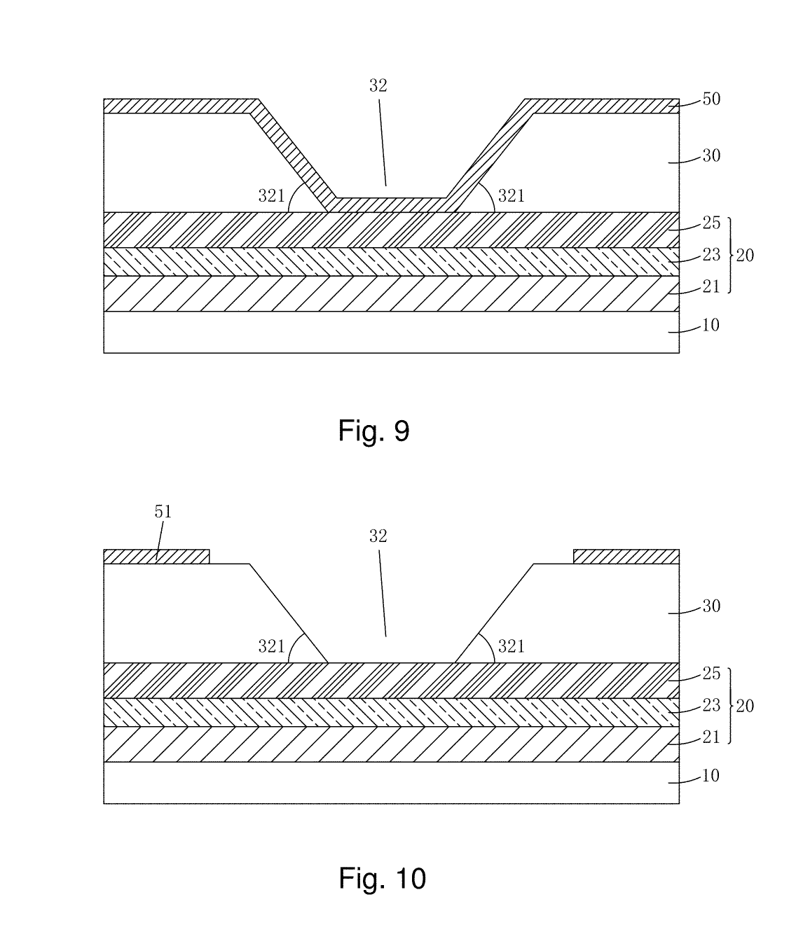

For a regular liquid crystal display panel, the method for manufacturing an array substrate further comprises Step 4: as shown in FIGS. 9-10, depositing an oxide conductive layer 50 on the planarization layer 30, and applying a photolithographic process to pattern the oxide conductive layer 50 so as to form a pixel electrode 51, wherein since the taper 321 of the grooves 32 formed in Step 3 is less steep, residues of the oxide conductive layer 50 in the grooves 32 can be avoided and product yield of the array substrate can be improved. Preferably, the oxide conductive layer 50 is formed of a material of indium tin oxide (ITO).

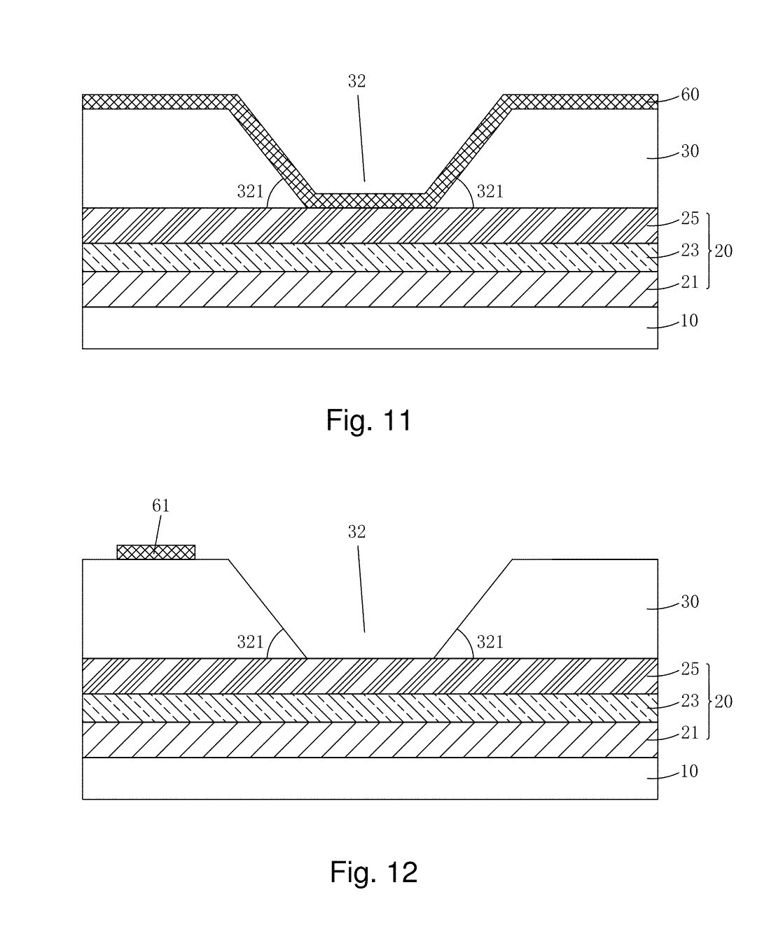

For an in-cell touch display panel, the method for manufacturing an array substrate further comprises Step 4′: as shown in FIGS. 11-12, depositing a metal layer 60 on the planarization layer 30, and applying a photolithographic process to pattern the metal layer 60 so as to form a touch sensing line (Rx) 61, wherein since the taper 321 of the grooves 32 formed in Step 3 is less steep, residues of the metal layer 60 in the grooves 32 can be avoided and product yield of the array substrate can be improved.

In summary, the present invention provides a method for manufacturing an array substrate, in which a planarization layer mask 40 comprises a strip pattern 401 that is provided for forming a groove and has two opposite sides along which taper modification patterns 402 are provided so as to reduce or lower taper 321 of a groove 32 formed in a planarization layer 30, making a slope thereof less steep, thereby preventing shorting of signal lines caused by residues of metal or ITO in a subsequent operation and thus increasing product yield. For the groove associated portion of an array substrate involving an in-cell touch structure, there is no need to change line for the touch sensing lines so as to lower down the difficulty of the operation and increase product yield.

Based on the description given above, those having ordinary skills of the art may easily contemplate various changes and modifications of the technical solution and technical ideas of the present invention and all these changes and modifications are considered within the protection scope of right for the present invention.

1. A method for manufacturing an array substrate, comprising the following steps:
(1) providing a base plate, forming a thin-film transistor (TFT) layer on the base plate, and then coating an organic photoresist material on the TFT layer to form a planarization layer;
(2) providing a planarization layer mask, wherein the planarization layer mask comprises a plurality of groove patterns corresponding to a circumferential area of the planarization layer and the groove patterns each comprise a strip pattern for forming a groove in the planarization layer and taper modification patterns arranged on two opposite sides of the strip pattern, wherein the taper modification patterns each comprise a plurality of miniature patterns densely and closely distributed along a side border of the strip pattern and the miniature patterns have a width that is reduced from the side border of the strip patterns in an outward direction; and
(3) using the planarization layer mask to subject the planarization layer to exposure and development so as to form a plurality of grooves in the circumferential area of the planarization layer, wherein since the planarization layer mask comprises the taper modification patterns that are provided on the two sides of each of the strip patterns for forming the grooves, the angle of side taper of the grooves is reduced to make a slope less steep;
wherein the miniature patterns each comprise a plurality of circular patterns that is sequentially lined up and in contact with each other in the outward direction and has diameters that are gradually reduced in the outward direction.

2. The method for manufacturing an array substrate as claimed in claim 1, wherein the base plate comprises a transparent plate; and the TFT layer comprises a buffer layer, a gate insulation layer, an interlayer dielectric layer, and an active layer, a gate electrode, and source/drain electrodes arranged among the buffer layer, the gate insulation layer, the interlayer dielectric layer, and the planarization layer.

3. (canceled)

4. The method for manufacturing an array substrate as claimed in claim 1, wherein the diameters of the circular patterns are in the range of 1-3 μm.

5-6. (canceled)

7. The method for manufacturing an array substrate as claimed in claim 1, wherein when the planarization layer is formed of a positive organic photoresist material, the groove patterns of the planarization layer mask are transparent, while the remaining portion is non-transparent; and when the planarization layer is formed of a negative organic photoresist material, the groove patterns of the planarization layer mask are non-transparent, while a remaining portion is transparent.

8. The method for manufacturing an array substrate as claimed in claim 1, wherein the taper of the grooves formed in step (3) has an angle between 20 degrees and 50 degrees.

9. The method for manufacturing an array substrate as claimed in claim 1 further comprising step (4): depositing an oxide conductive layer on the planarization layer and applying a photolithographic process to pattern the oxide conductive layer so as to form a pixel electrode, wherein since the taper of the grooves formed in step (3) is less steep, residues of the oxide conductive layer in the grooves is avoided.

10. The method for manufacturing an array substrate as claimed in claim 1 further comprising step (4′): depositing a metal layer on the planarization layer and applying a photolithographic process to pattern the metal layer so as to form a touch sensing line, wherein since the taper of the grooves formed in step (3) is less steep, residues of the metal layer in the grooves is avoided.
